(19) United States
(12) Patent Application Publication
(10) Pub. No.: US 2024/0369197 A1
(43) Pub. Date: Nov. 7, 2024

(54) LIGHTING DEVICE

(71) Applicant: Denka Company Limited, Chuo-ku, Tokyo (JP)

(72) Inventor: Masahiro KONISHI, Tokyo (JP)

(73) Assignee: Denka Company Limited, Chuo-ku, Tokyo (JP)

(21) Appl. No.: 18/574,484

(22) PCT Filed: Jun. 21, 2022
(86) PCT No.: PCT/JP2022/024659

§ 371 Date: Dec. 27, 2023

(30) Foreign Application Priority Data
Jun. 28, 2021 (JP) 2021-106374

(51) Int. Cl. F21K 9/64; F21K 9/232; F21K 9/238

(52) U.S. Cl. CPC F21K 9/64; F21K 9/232; F21K 9/238

(57) ABSTRACT

A light emitting device (100) (lighting device) includes a phosphor application printed wiring board (30) in which a phosphor layer (36) is provided on a substrate surface, a first light emitting unit (20A) provided in the phosphor application printed wiring board (30) and outputting light having a peak wavelength of a first wavelength, and a second light emitting unit (20B) provided in the phosphor application printed wiring board (30) and outputting light having a peak wavelength of a second wavelength different from the first wavelength. The phosphor layer (36) is provided separately from the first light emitting unit (20A) and the second light emitting unit (20B) at least around the first light emitting unit (20A) and the second light emitting unit (20B). A light emission peak wavelength includes a phosphor located in a visible light region when the light having the first wavelength and the light having the second wavelength are emitted as excitation light.

### TECHNICAL FIELD

The present invention relates to a lighting device.

### BACKGROUND ART

Patent Document 1 discloses a light emitting diode (LED) lighting fixture including a substrate on which a light emitting element (LED element) is mounted.

### RELATED DOCUMENT

### Patent Document

[Patent Document 1] Chinese Patent Publication No. 106163113

### SUMMARY OF THE INVENTION

### Technical Problem

For example, in a case of the LED lighting fixture in Patent Document 1, there is no disclosure regarding a lighting technique for causing a plurality of light emitting units (light emitting elements) to efficiently emit light and to emit the light with a desired light emission color, and there has been a demand for a new technique.

The present invention aims to provide a lighting technique for efficiently emitting light and emitting light in a desired light emission color in a lighting device (light emitting device) including a light emitting substrate including a plurality of light emitting units.

### SOLUTION TO PROBLEM

According to the present invention, the following aspects of the invention are provided.

### 1

There is provided a lighting device including a phosphor application printed wiring board in which a phosphor layer is provided in a substrate surface, at least one first light emitting unit provided in the phosphor application printed wiring board and outputting light having a peak wavelength of a first wavelength, at least one second light emitting unit provided in the phosphor application printed wiring board and outputting light having a peak wavelength of a second wavelength different from the first wavelength,
wherein the phosphor layer is provided separately from the first light emitting unit and the second light emitting unit around at least the first light emitting unit and the second light emitting unit, and includes a phosphor in which a light emission peak wavelength is in a visible light region when the light having the first wavelength and the light having the second wavelength are emitted as excitation light.

### 2

The lighting device according to [1], the peak wavelength of the first wavelength is a wavelength region of visible light.

### 3

The lighting device according to [1] or [2], the peak wavelength of the second wavelength is in a range of 415 nm or longer and 460 nm or shorter.

### 4

The lighting device according to [1] or [2], the peak wavelength of the second wavelength is in a range of 315 nm or longer and 415 nm or shorter.

### 5

The lighting device according to any one of [1] to [4], a sealing material that seals a light emitting element of the second light emitting unit is colorless and transparent.

### 6

The lighting device according to any one of [1] to [5] further includes a serial body in which the at least one first light emitting unit and the at least one second light emitting unit are connected in series.

### 7

The lighting device according to [6], the serial body includes a plurality of the first light emitting units connected in series.

### 8

The lighting device according to [6] or [7], the serial body includes a plurality of the second light emitting units connected in series.

### 9

The lighting device according to [6] or [7], the serial body includes a plurality of the second light emitting units connected in parallel.

### 10

The lighting device according to any one of [6] to [9], a plurality of the serial bodies are connected in parallel.

### 11

The lighting device according to any one of [1] to [10], a light emitting element of the first light emitting unit and a light emitting element of the second light emitting unit are light emitting diode elements.

### 12

The lighting device according to any one of [1] to further includes an adjusting resistor that adjusts a current flowing through the first light emitting unit.

### 13

The lighting device according to any one of [1] to further includes a circuit pattern on which the first light emitting unit and the second light emitting unit are mounted,
where in the circuit pattern includes a positive potential portion provided on a substrate center side and a ground potential portion provided on a substrate outer peripheral side, as a path for supplying electric power to the first light emitting unit and the second light emitting unit.

### 14

The lighting device according to any one of [1] to further includes a photocatalyst unit that exhibits a photocatalyst function by using the light having the second wavelength output from the second light emitting unit.

### Advantageous Effects Of Invention

It is possible to provide a lighting technique for efficiently emitting light and emitting light in a desired light emission color in a lighting device (light emitting device) including a light emitting substrate including a plurality of light emitting units.

### BRIEF DESCRIPTION OF THE DRAWINGS

FIG. 1 is a perspective view showing a schematic configuration of a light emitting device of an embodiment.

FIG. 2 is an exploded perspective view showing a schematic configuration of the light emitting device of the embodiment.

FIG. 3 is a plan view of a light emitting substrate of the embodiment.

FIG. 4 is a plan view of the light emitting substrate which shows a state where a circuit pattern layer of the embodiment is exposed.

FIG. 5 is a view schematically showing a partial sectional view of the light emitting substrate of the embodiment.

FIG. 6 is a circuit diagram of a light emitting unit of the embodiment.

FIG. 7 is a circuit diagram showing a variation in connection aspect of serial bodies of the light emitting units of the embodiment.

FIG. 8 is a view for describing a basic light emitting operation of the light emitting substrate of the embodiment.

FIG. 9 is a plan view for describing a light emitting operation of the light emitting substrate in which a first light emitting unit and a second light emitting unit of the embodiment are mixed.

FIG. 10 is a sectional view for describing a light emitting operation of the light emitting substrate in which the first light emitting unit and the second light emitting unit of the embodiment are mixed.

### DESCRIPTION OF EMBODIMENTS

### Outline of Light Emitting Device 100

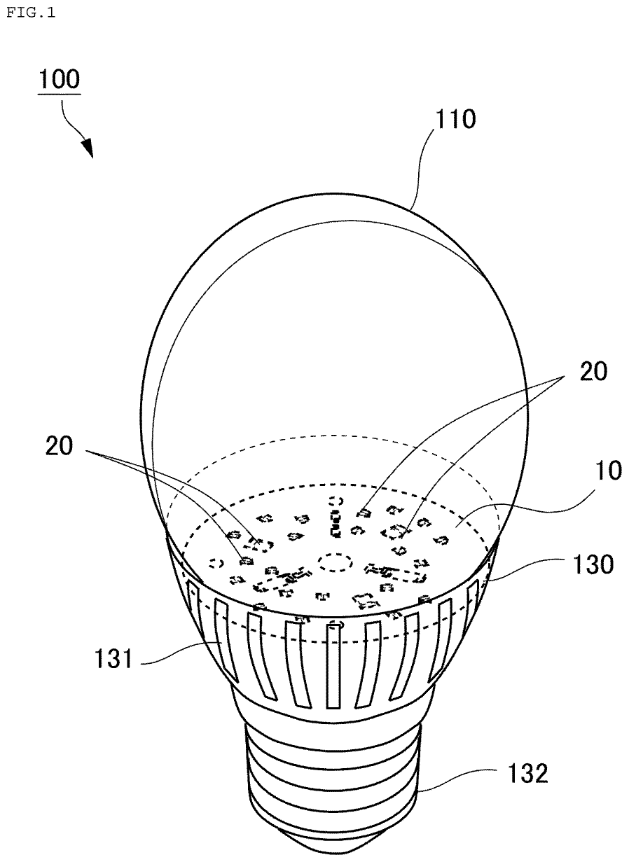

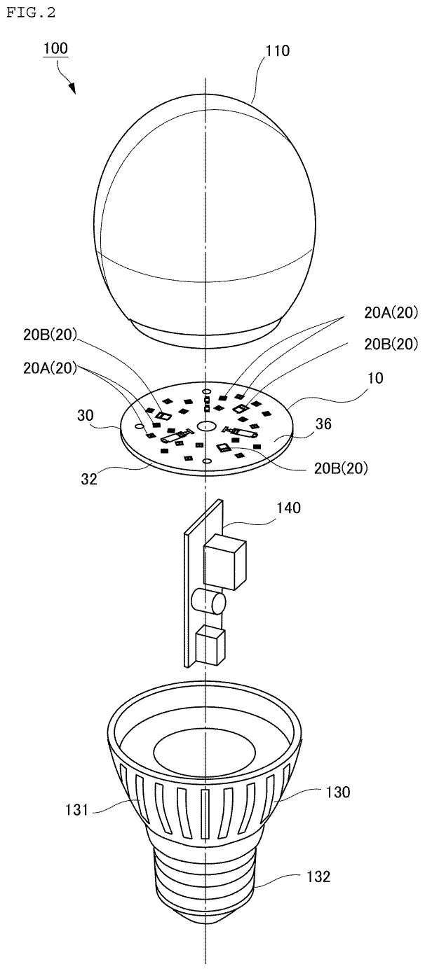

FIG. 1 is a perspective view of a light emitting device 100 (lighting device) of the present embodiment. FIG. 2 is an exploded perspective view of the light emitting device 100. The light emitting device 100 is an LED bulb, and includes a cover member 110, a light emitting substrate 10, a body portion 130, and a drive circuit 140. The light emitting device 100 may be configured to have a substantially conical, cylindrical shape, or a rectangular parallelepiped shape (box shape) in addition to a bulb shape. The light emitting device 100 may be configured as a bulb used indoors and outdoors, or an outdoor street lamp. Furthermore, the light emitting device 100 may be configured as a high-output lighting device used for stadium lighting or exterior lighting of a large-scale building (so-called tower lighting).

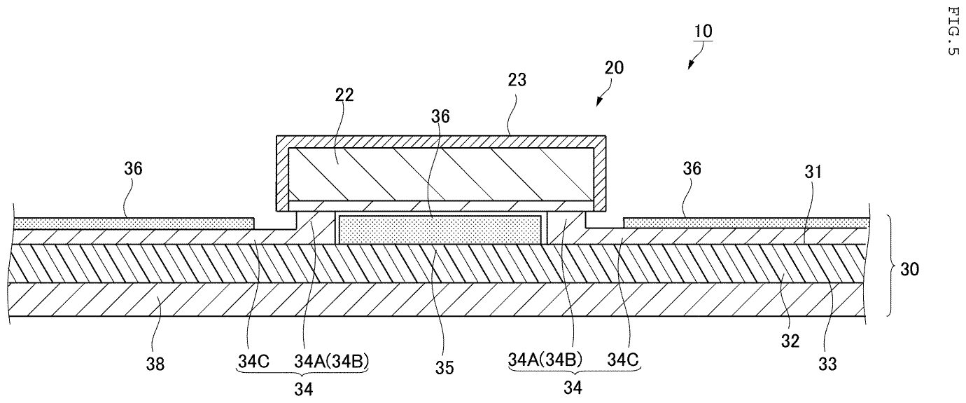

The light emitting substrate 10 has a substantially circular shape in a top view, and a plurality of light emitting units 20 are mounted thereon. For example, the light emitting unit 20 is a chip scale package (CSP) in which a flip chip LED (LED) is incorporated as the light emitting element 22 as described later in FIG. 5. As the light emitting unit 20, without being limited to the CSP, for example, a surface mount device (SMD) type LED or a flip chip LED can be used. Although a substantially circular shape is shown in the top view as an example of a shape of the light emitting substrate 10, a rectangular shape or another shape is appropriately selected, depending on the shape of the light emitting device 100, or the mounting number and a disposition of the light emitting units 20. The light emitting substrate 10 is configured so that the plurality of light emitting units 20 are mounted on a phosphor application printed wiring board 30 in which the phosphor layer 36 is provided on one surface of an insulating substrate 32.

For example, the body portion 130 is formed of die-cast aluminum. An inner space is formed in the body portion 130, and a base 132 is attached to a lower portion of the body portion 130. The body portion 130 is provided with a heat radiating opening 131 for discharging internal heat. A heat radiating coating material is applied to a surface of the body portion 130 for electrical insulation.

The drive circuit 140 is disposed in an inner space of the body portion 130, and the above-described light emitting substrate 10 is attached to an upper portion thereof to cover the inner space. When a cooling fan is provided, a temperature sensor is provided inside the light emitting device 100, and the drive circuit 140 performs driving control of the cooling fan. In this manner, the inside of the light emitting device 100 can be controlled to be in a desired temperature range. In addition, a heat radiating fin may be provided on a lower surface of the light emitting substrate 10, that is, on the drive circuit 140 side.

For example, the cover member 110 is provided in a spherical shape made of a thermoplastic resin or glass, and is open on a lower side in the drawing (that is, on the body portion 130 side). The cover member 110 is attached at an open portion to cover an upper portion of the body portion 130 to which the light emitting substrate 10 is attached. The cover member 110 may contain a diffusing material.

The drive circuit 140 includes an LED driver IC or a capacitor, and drives the light emitting unit 20 to emit light by performing PWM (Pulse Width Modulation) control on an on/off duty of the light emitting unit 20. A partial configuration of the drive circuit 140 may be mounted on the light emitting substrate 10.

In the light emitting device 100, multiple types of light emitting units 20 are provided in the phosphor application printed wiring board 30 having the phosphor layer 36. The light emitting unit 20 includes a first light emitting unit 20A that outputs light having a peak wavelength of a first wavelength and a second light emitting unit 20B that outputs light having a peak wavelength of a second wavelength different from the first wavelength.

The first light emitting unit 20A outputs light in a wavelength region of visible light, for example, light having a spectrum of white light.

The second light emitting unit 20B outputs blue light having a peak wavelength of the second wavelength in a range of 415 nm or longer and 460 nm or shorter, or purple light having a peak wavelength of the second wavelength in a range of 315 nm or longer and 415 nm or shorter (near-ultraviolet light). Hereinafter, a form in which the second light emitting unit 20B outputs the blue light having a wavelength of 450 nm will be described.

The phosphor layer 36 is provided at least around the first light emitting unit 20A and the second light emitting unit 20B. The phosphor layer 36 includes a phosphor in which a light emission peak wavelength is in a visible light region when the blue light is emitted as excitation light. In the present embodiment, the phosphor layer 36 is set so that the light excited by the blue light having a wavelength of 450 nm is complementary light (here, yellow light) with respect to the blue light. As a result, combined light of the light of the second light emitting unit 20B and the light of the phosphor layer 36 becomes white.

### Light Emitting Substrate 10

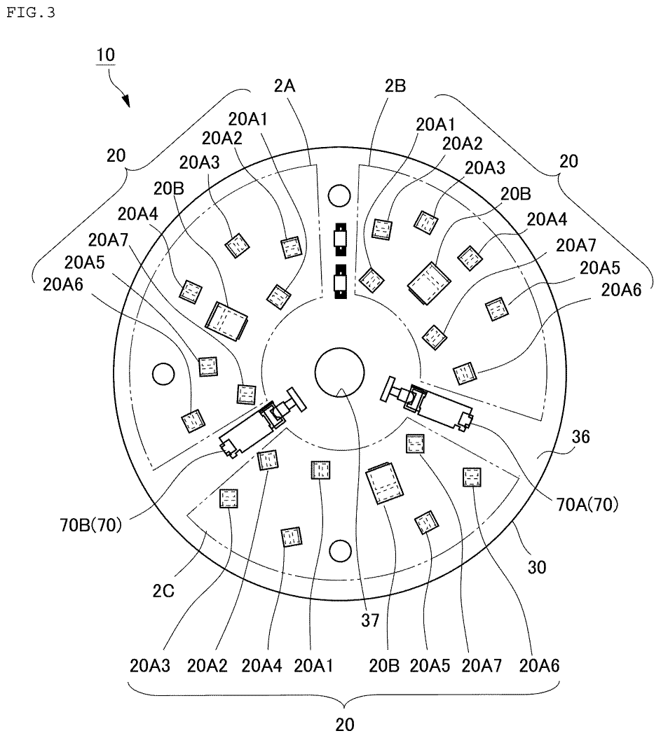

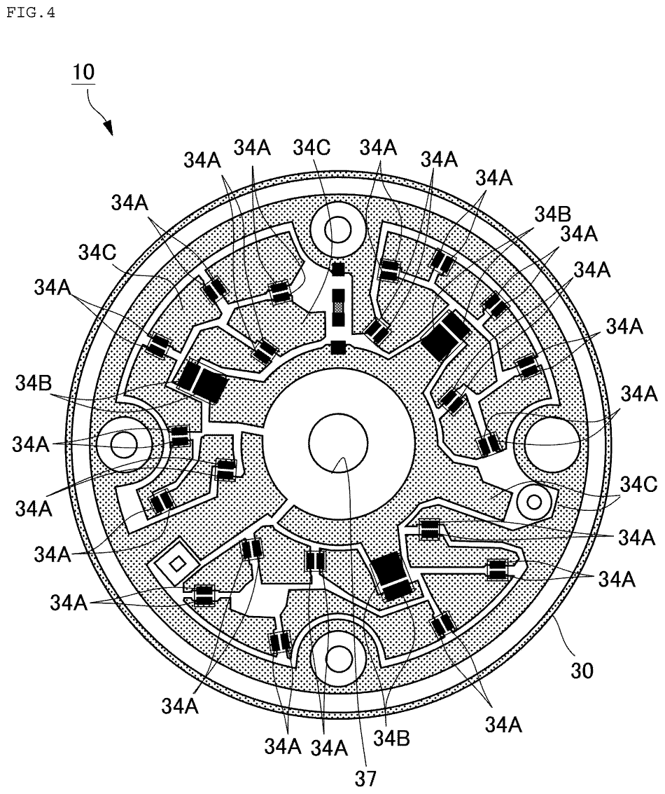

Next the light emitting substrate 10 will be described mainly with reference to FIGS. 3 to 5. FIG. 3 is a plan view when the light emitting substrate 10 is viewed from a surface 31 side. FIG. 4 is a plan view of the light emitting substrate 10 in a state where a circuit pattern layer 34 is exposed by omitting the light emitting unit 20 and a phosphor layer 36 from the light emitting substrate 10 in FIG. 3. FIG. 5 is a sectional view of the light emitting substrate 10, and is a sectional view schematically showing a state where one light emitting unit 20 is paid attention.

As shown in FIGS. 3 and 4, the light emitting substrate 10 has a circular shape in a top view, for example. The light emitting substrate 10 includes the phosphor application printed wiring board 30, a plurality of the light emitting units 20, a connector 70, and an electronic component (not shown). The plurality of light emitting units 20, the connector 70, and the electronic component are mounted on the phosphor application printed wiring board 30.

A vertically penetrating central opening 37 is provided at a center of the light emitting substrate 10. The plurality of light emitting units 20 are connected to the connector 70, and are connected to the drive circuit 140 by a lead wire (not shown) from the central opening 37. The connector 70 includes an anode side connector (+) 70A and a ground (GND) side connector (GND) 70B.

### Light Emitting Unit 20

As mainly shown in FIG. 5, in each of the light emitting units 20 (first light emitting unit 20A and second light emitting unit 20B), as an example, a flip chip LED (light emitting diode element) which is the light emitting element 22 is sealed with a sealing resin 23 (sealing material). Basic structures of the first light emitting unit 20A and the second light emitting unit 20B are the same as each other, and a difference is that a spectral distribution (that is, color temperature) of the output light is different. The difference is mainly based on a type of the phosphor included in the sealing resin 23 or the presence or absence of the phosphor.

For example, the light emitting element 22 is an LED configured by using indium gallium nitride (InGaN), and outputs the blue light having a peak wavelength of 450 nm.

In the first light emitting unit 20A, the light emitting element 22 is sealed with the sealing resin 23 to which a yellow light emitting phosphor is added. As a result, light excited and emitted by the light emitting element 22 is subjected to color conversion by the phosphor of the sealing resin 23, and is output in a spectral distribution recognized as white light, for example.

In the second light emitting unit 20B, the light emitting element 22 is sealed with the colorless and transparent sealing resin 23 to which the phosphor is not added. As a result, the light excited and emitted by the light emitting element 22 is output with a spectral distribution recognized as the blue light having a peak wavelength of 450 nm without being subjected to color conversion by the sealing resin 23.

### Phosphor Application Printed Wiring Board 30

The phosphor application printed wiring board 30 includes the insulating substrate 32, the circuit pattern layer 34 provided on the surface 31 of the insulating substrate 32, the phosphor layer 36, and core metal 38 provided on a back surface 33 of the insulating substrate 32.

### Insulating Substrate 32

As an example, the insulating substrate 32 has the following characteristics. As described above, as an example, a shape is a circular shape when viewed from the surface 31 side and the back surface 33 side. As an example, a material is an insulating material including a bismaleimide resin and glass cloth. As an example, a thickness is 100 μm.

As an example, each coefficient of thermal expansion (CTE) in a longitudinal direction and a lateral direction is 10 ppm/° C. or lower in a range of 50° C. to 100° C. In addition, from another viewpoint, as an example, each coefficient of thermal expansion (CTE) in the longitudinal direction and the lateral direction is 6 ppm/° C. This value is approximately equal (90% to 110%, that is, within +10%) to a value in a case of the light emitting unit 20 of the present embodiment.

As an example, a glass transition temperature is higher than 300° C.

As an example, a storage modulus is higher than 1.0×10¹⁰ Pa and lower than 1.0×10¹¹ Pa in a range of 100°° C. to 300° C.

As an example, each flexural modulus in the longitudinal direction and lateral direction is 35 GPa and 34 GPa under a normal condition.

As an example, a hot flexural modulus in the longitudinal direction and lateral direction is 19 GPa at 250° C. As an example, a water absorption ratio is 0.13% when being left for 24 hours in an environment at a temperature of 23° C. As an example, a dielectric constant is 4.6 under a normal condition of 1 MHz. As an example, a dielectric loss tangent is 0.010 under the normal condition of 1 MHZ.

### Circuit Pattern Layer 34

The circuit pattern layer 34 is a metal layer (copper foil layer as an example) provided on the surface 31 of the insulating substrate 32, and is conductive with the connectors 70 (connector (+) 70A and connector (GND) 70B). The circuit pattern layer 34 supplies electric power supplied from a power source (drive circuit 140) through a lead wire connected to the connector 70 to the light emitting units 20 (first light emitting unit 20A and second light emitting unit 20B).

A portion of the circuit pattern layer 34 is an electrode pair 34A to which the first light emitting unit 20A is joined and an electrode pair 34B to which the second light emitting unit 20B is joined. A portion of the circuit pattern layer 34 other than the electrode pairs 34A and 34B is referred to as a wiring portion 34C. A circuit pattern of the circuit pattern layer 34 is appropriately set depending on the disposition of the first light emitting unit 20A or the second light emitting unit 20B. For example, a configuration including a positive potential portion provided on a substrate center side and a ground potential portion provided on a substrate outer peripheral side can be adopted. The positive potential portion is connected to the connector (+) 70A. The ground potential portion is connected to the connector (GND) 70B.

### Phosphor Layer 36

As an example, the phosphor layer 36 of the present embodiment is provided on the surface 31 of the insulating substrate 32 to cover a portion in the circuit pattern layer 34 other than the electrode pairs 34A and 34B, the connector 70, and the electronic component mounted on the phosphor application printed wiring board 30. In other words, the phosphor layer 36 is provided separately from the first light emitting unit 20A and the second light emitting unit 20B. That is, the first light emitting unit 20A and the second light emitting unit 20B may have a phosphor layer as the sealing material. However, the phosphor layer 36 provided on the surface 31 of the insulating substrate 32 has a configuration different from that of the phosphor layer of the sealing material of the first light emitting unit 20A and the second light emitting unit 20B.

For example, the phosphor layer 36 is an insulating layer which includes a phosphor (aggregate of a plurality of phosphor particles) and a binder (to be described later), and in which the plurality of phosphor particles are dispersed in the binder. The phosphor included in the phosphor layer 36 has a property of exciting the emitted light of the light emitting unit 20 as the excitation light. Specifically, the phosphor of the present embodiment has a property in which the light emission peak wavelength is in the visible light region when the emitted light of the light emitting unit 20 is used as the excitation light. For example, the binder may be an epoxy-based, acrylate-based, or silicone-based binder having insulating properties equivalent to those of a binder included in a solder resist.

The phosphor included in the phosphor layer 36 is appropriately selected depending on a light emission color of the second light emitting unit 20B (that is, the second peak wavelength) and any color of the light to be emitted by the phosphor layer 36. For example, the phosphor layer 36 is one or more types of the phosphors selected from a group consisting of an x-type sialon phosphor containing Eu, a β-type sialon phosphor containing Eu, a CASN phosphor containing Eu, and a SCASN phosphor containing Eu. The phosphors described above are examples in the present embodiment, and may be phosphors other than the phosphors described above, such as YAG, LuAG, BOS, and other visible light excitation phosphors.

The α-type sialon phosphor containing Eu is represented by General Formula MₓEu_{y}Si₁₂₋₍ₘ₊ₙ₎Al₍ₘ₊ₙ₎OₙN₁₆₋ₙ. In General Formula described above, M is one or more types of elements containing at least Ca, which are selected from a group consisting of Li, Mg, Ca, Y, and lanthanide elements (however, La and Ce are excluded). When a valence of M is defined as a, ax+2y=m, and x is 0<x≤1.5, 0.3≤m<4.5, and 0<n<2.25.

The β-type sialon phosphor containing Eu is a phosphor in which divalent europium (Eu²⁺) is solid-dissolved as a light emission center in β-type sialon represented by General Formula: Si_{6-z}Al_{z}O_{z}N_{8-z} (z=0.005 to 1).

In addition, examples of nitride phosphors include the CASN phosphor containing Eu and the SCASN phosphor containing Eu.

For example, the CASN phosphor containing Eu (example of the nitride phosphor) is referred to as a red phosphor represented by a formula CaAlSiN₃: Eu²⁺, in which Eu²⁺ is used as an activator, and a crystal formed of alkali earth silicon nitride is used as a matrix. In a definition of the CASN phosphor containing Eu in the present specification, the SCASN phosphor containing Eu is excluded.

For example, the SCASN phosphor containing Eu (example of nitride phosphors) is referred to as a red phosphor represented by a formula (Sr, Ca) AlSiN₃: Eu²⁺, in which Eu²⁺ is used as the activator, and a crystal formed of alkali earth silicon nitride is used as the matrix.

### Core Metal 38

The core metal 38 is a metal plate formed of copper or aluminum disposed on the back surface 33 of the insulating substrate 32, and improves heat radiating capability. A heat radiating unit such as a heat radiating fin is attached to the core metal 38 when necessary.

### Disposition and Connection Aspect of Plurality of Light Emitting Units 20

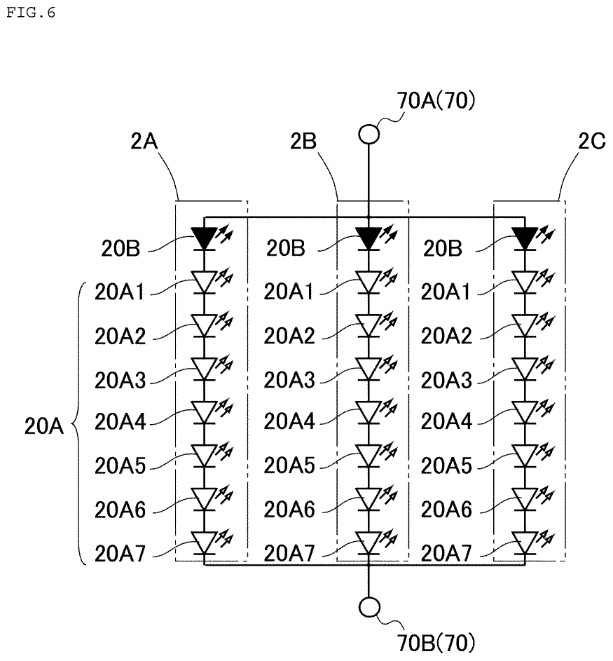

With reference to FIGS. 3, 4, and 6, a disposition and a connection aspect of the light emitting units 20 will be described. FIG. 6 is a view showing a circuit example of the light emitting unit 20.

The plurality of light emitting units 20 are disposed over the entire surface 31 side of the insulating substrate 32. In the present embodiment, three sets of serial bodies in which seven first light emitting units 20A and one second light emitting unit 20B are connected in series as one set are provided in parallel. As shown in FIG. 3, for convenience, a region of the light emitting substrate 10 will be described by dividing the region into three equal regions of first to third regions 2A to 2C in a circumferential direction in a top view.

In each of the first to third regions 2A to 2C, total eight light emitting units 20 including seven first light emitting units 20A (first light emitting unit 20A1 to first light emitting unit 20A7) and one second light emitting unit 20B are provided. The eight light emitting units 20 are configured as serial bodies connected in series, and three serial bodies are connected in parallel between the connector (+) 70A and the connector (GND) 70B. As described above, the first light emitting unit 20A outputs the white light, and the second light emitting unit 20B outputs the blue light.

More specifically, in the serial body of the first region 2A, the second light emitting unit 20B, the first light emitting unit 20A1, the first light emitting unit 20A2, . . . and the first light emitting unit 20A7 are connected in series in this order from the connector (+) 70A to the connector (GND) 70B.

In the serial body of the second region 2B and the third region 2C, the same connection aspect is also adopted.

A lead wire is connected to the connector (+) 70A and is connected to the above-described drive circuit 140 through the central opening 37. In addition, a lead wire is connected to the connector (GND) 70B, and is connected to a predetermined ground (GND).

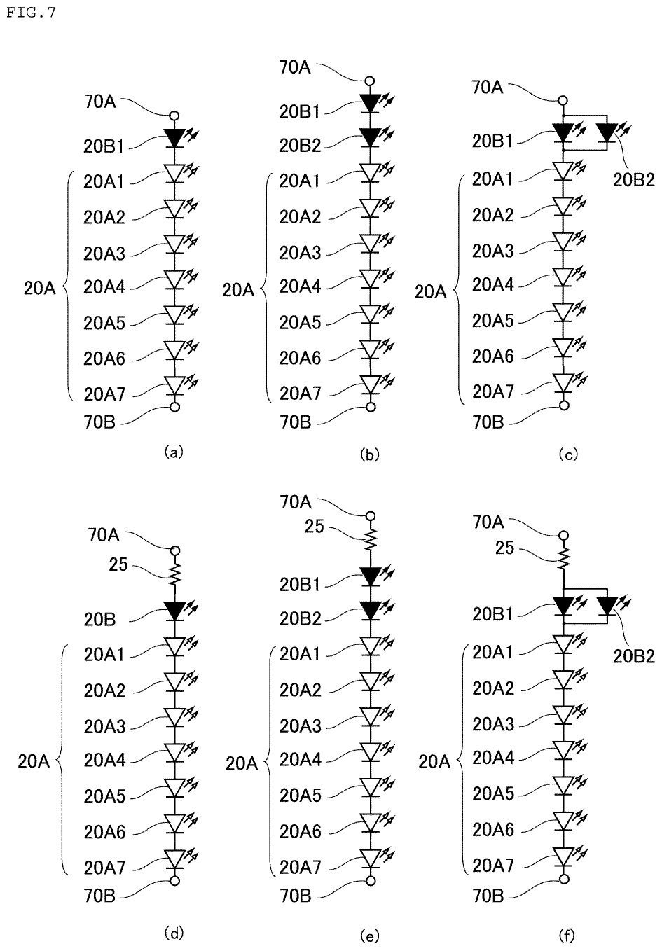

With reference to FIG. 7, six examples of the connection aspect of the serial body configured by the second light emitting unit 20B, the first light emitting unit 20A1, the first light emitting unit 20A2, and the first light emitting unit 20A7 will be described.

FIG. 7(a) shows a basic connection aspect of the above-described serial body. That is, the second light emitting unit 20B, the first light emitting unit 20A1, the first light emitting unit 20A2, . . . , and the first light emitting unit 20A7 are connected in series in this order from the connector (+) 70A to the connector (GND) 70B.

FIG. 7(b) shows a modification example of the connection aspect in FIG. 7(a), and two second light emitting units 20B are connected in series. That is, the second light emitting unit 20B1 and the second light emitting unit 20B2 are connected in series in this order between the connector (+) 70A and the first light emitting unit 20A1.

FIG. 7(c) shows a modification example of the connection aspect in FIG. 7(b), and two second light emitting units 20B are connected in parallel. That is, the second light emitting unit 20B1 and the second light emitting unit 20B2 are connected in parallel between the connector (+) 70 and the first light emitting unit 20A.

FIG. 7(d) shows a modification example of the connection aspect in FIG. 7 (a), and a current adjusting resistor 25 for adjusting a current flowing through the serial body is connected between the second light emitting unit 20B and the connector (+) 70A. Since the current adjusting resistor 25 is provided in each of the serial bodies, variations in the light emitting elements 22 can be adjusted, and light emission intensity of each of the serial bodies can be adjusted to a desired level (to be generally the same).

FIG. 7(e) is a modification example of the connection aspect in FIG. 7(b), and a current adjusting resistor 25 for adjusting the current flowing through the serial body is connected between the second light emitting unit 20B1 and the connector (+) 70A.

FIG. 7(f) shows a modification example of the connection aspect in FIG. 7(c), and the current adjusting resistor 25 for adjusting the current flowing through the serial body is connected between the second light emitting unit 20B1 and the connector (+) 70A.

### Light Emitting Operation Performed by Light Emitting Substrate 10

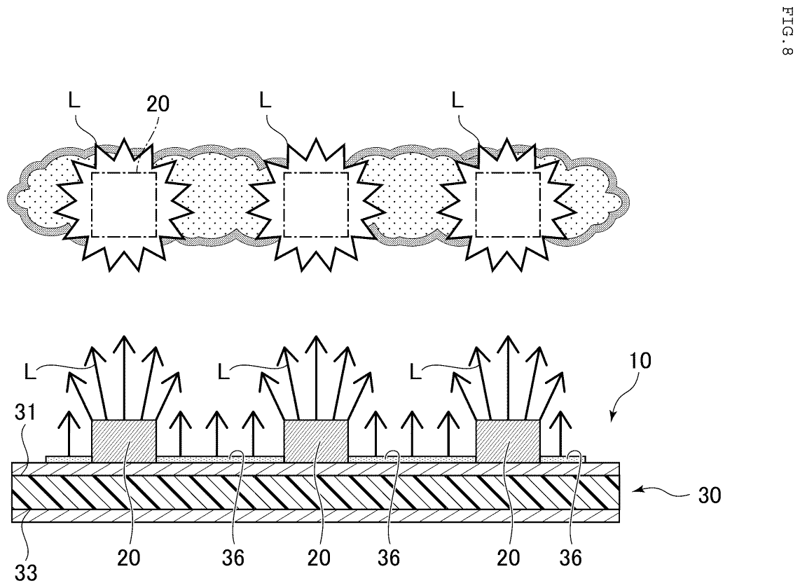

With reference to FIG. 8, a basic light emitting operation of the light emitting substrate 10 in which the phosphor layer 36 is provided on the surface 31 will be described.

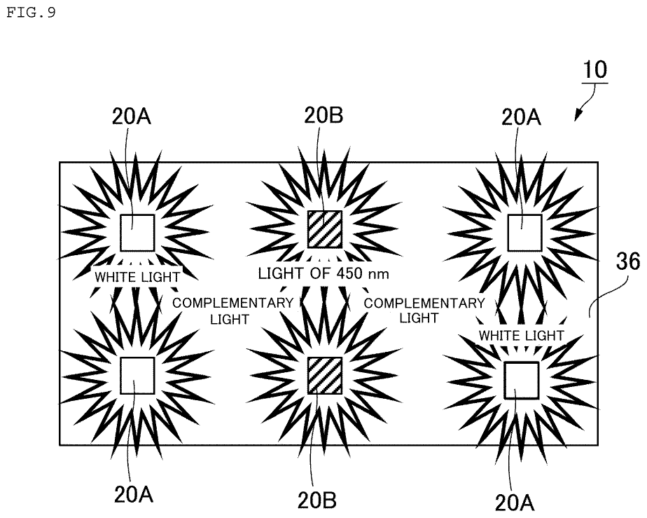

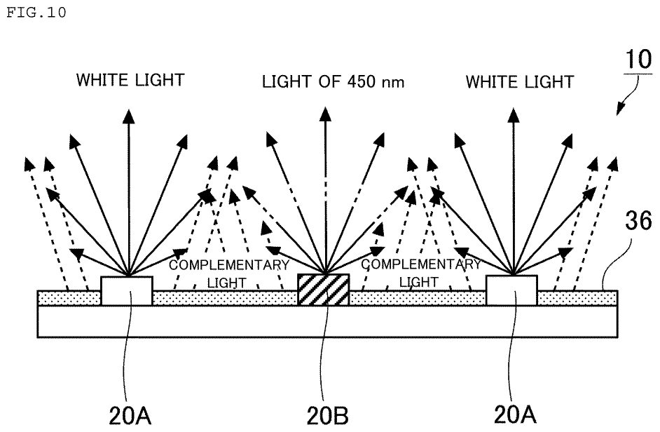

Subsequently, with reference to FIGS. 9 and 10, the light emitting operation when the first light emitting unit 20A and the second light emitting unit 20B are mixed as the light emitting unit 20 will be described.

When the drive circuit 140 is turned on, as shown in FIG. 8, the light emitting unit 20 emits light L to be dispersed in a radial shape, and a portion of the light L reaches the surface 31 side of the phosphor application printed wiring board 30. Hereinafter, a behavior of the light L will be described in terms of a traveling direction of the emitted light L. Here, the light L includes a wavelength for exciting the phosphor of the phosphor layer 36 and outputting the excitation light. Specifically, the phosphor (visible light excited phosphor) in which the phosphor dispersed in the phosphor layer 36 has an excitation peak in the blue light is used.

A portion of the light L emitted from the light emitting unit 20 is emitted to the outside of the bulb, that is, to the outside of the cover member 110 without being incident on the phosphor layer 36. In this case, the wavelength of the light L remains the same as the wavelength of the light L when emitted from the light emitting unit 20.

A portion of the light L emitted from the light emitting unit 20 is incident on the phosphor layer 36. Moreover, when the light L incident on the phosphor layer 36 collides with the phosphor dispersed in the phosphor layer 36, the phosphor is excited to emit the excitation light. The excitation light in the phosphor layer 36 is directly emitted from the phosphor layer 36, but a portion of the excitation light is directed toward to the lower circuit pattern layer 34. The excitation light directed toward the circuit pattern layer 34 is emitted to the outside by being reflected on the circuit pattern layer 34. Depending on a type of phosphor in the phosphor layer 36, the wavelength of the light L may be different. However, in any case, the light L is subjected to wavelength conversion. Since the phosphor layer 36 is provided in this way, unlike a case where the phosphor layer 36 is not provided, the light is also emitted from the phosphor layer 36. Therefore, glares of the emitted light are reduced.

With reference to FIGS. 9 and 10, the light emitting operation when the first light emitting unit 20A and the second light emitting unit 20B are mixed as the light emitting unit 20 will be described. FIG. 9 is a plan view schematically showing the light emitting substrate 10 in which the first light emitting unit 20A and the second light emitting unit 20B are mixed. FIG. 10 is a sectional view schematically showing the light emitting substrate 10 in which the first light emitting unit 20A and the second light emitting unit 20B are mixed. As described above, the first light emitting unit 20A outputs the white light, and the second light emitting unit 20B outputs the light having a peak wavelength of 450 nm.

The phosphor layer 36 includes a phosphor which emits the light through fluorescence excitation by using the light (peak wavelength: 450 nm) of the second light emitting unit 20B. In the light emitted from the second light emitting unit 20B, the light incident on the phosphor layer 36 is converted by the phosphor into light different from the light of the second light emitting unit 20B, for example, complementary light. As a result, the light of the second light emitting unit 20B is output by combining the directly output light and the light excited and output by the phosphor layer 36, and is recognized as the white light as a whole.

In this way, the light emitting device 100 includes the first light emitting unit 20A that outputs the white light, the second light emitting unit 20B that outputs the blue light, and the phosphor layer 36 including the phosphor that performs fluorescence excitation by using the blue light. Accordingly, the glares can be reduced, and light closer to more natural white light can be output. In addition, a color tone output can be adjusted as the light emitting device 100 by adjusting the disposition and light intensity (output and the number) of the second light emitting units 20B, the material, the thickness, the position, and the region of the phosphor layer 36.

### Other Functions (Photocatalyst Function)

The light emitting device 100 may be provided with a photocatalyst unit having a photocatalyst. The photocatalyst unit exhibits a photocatalyst function by using the light having the second wavelength output from the second light emitting unit 20B. That is, the second light emitting unit 20B serves as a photocatalyst exciting light source. As the light having the second wavelength output from the second light emitting unit 20B, for example, although it depends on the photocatalyst to be used, the light having a wavelength in a range of 315 nm to 415 nm, that is, the near-ultraviolet light (ultraviolet ray) can be used. In addition, the blue light having a peak wavelength of the second wavelength in a range of 415 nm longer and 460 nm or shorter can be used.

As the photocatalyst, for example, titanium oxide can be used when the light having the second wavelength is the near-ultraviolet light (ultraviolet ray). When the light having the second wavelength is the blue light, titanium oxide doped with ions such as tungsten oxide (used in combination with a catalyst such as platinum), nitrogen, sulfur, and carbon or iron-supported titanium oxide can be used. For example, the photocatalyst unit can apply a coating material whose main component is the photocatalyst (titanium oxide or tungsten oxide) described above as an example to an inner surface of the cover member 110 or the phosphor application printed wiring board 30.

When the photocatalyst (titanium oxide or tungsten oxide) of the photocatalyst unit is exposed to the light having the second wavelength output from the second light emitting unit 20B, oxidation and reduction reactions occur on a surface of the photocatalyst, and active oxygen having decomposing power is generated to exhibit odor removal, antibacterial, and antivirus functions. The inside of the cover member 110 communicates with the outside of the light emitting device 100 through the central opening 37 and the heat radiating opening 131. In this manner, odor removal, antibacterial, and antivirus functions can be fulfilled on a surrounding environment of the light emitting device 100. When the second light emitting unit 20B outputs the near-ultraviolet light (ultraviolet ray), it is preferable to perform a process such as kneading an ultraviolet ray absorber in the cover member 110, and to prevent the near-ultraviolet light (ultraviolet ray) from being output to the outside of the cover member 110. In other words, when the second light emitting unit 20B outputs the blue light to exhibit the photocatalyst function, it is not necessary to consider influence of ultraviolet ray on a human body. Therefore, there is no limitation in installation positions from this viewpoint. For example, the photocatalyst may be provided on an outer surface of the cover member 110.

In addition, when the second light emitting unit 20B is used as a photocatalyst exciting light source, light having a short wavelength, such as the blue light or the near-ultraviolet light (ultraviolet ray), is preferably used as the light having the second wavelength. In this case, an output of the light emitting device 100 tends to be shifted to the blue side. However, the phosphor layer 36 outputs the excitation light (light having a wavelength on a red side with respect to the second wavelength) by using the light having the second wavelength. In this manner, the shift to the blue side can be suppressed. In particular, when the light emitting device 100 outputs light in a bulb color, the shift to the blue side visually and clearly appears. Therefore, the shift to the blue side is extremely suppressed by the phosphor layer 36. That is, while the photocatalyst function is added to the light emitting device 100, the phosphor layer 36 can suppress the shift to the blue side of the light emitted from the light emitting device 100.

In some cases, a wavelength band having satisfactory excitation efficiency of fluorescence light emission in the phosphor layer 36 and a wavelength band having satisfactory catalytic reaction efficiency (excitation efficiency) in the photocatalyst unit may deviate from each other. For example, in some cases, the fluorescence light emission in the phosphor layer 36 may exhibit extremely high efficiency in the vicinity of 450 nm. In contrast, the catalytic reaction in the photocatalyst unit may exhibit extremely high efficiency at 405 nm. In that case, when the fluorescence light emission in the phosphor layer 36 is important, an element that outputs light of 450 nm can be used as the light emitting element 22 of the second light emitting unit 20B. When the catalytic reaction in the photocatalyst unit is important, an element that outputs light of 405 nm can be used as the light emitting element 22 of the second light emitting unit 20B. When both are important, a configuration of using the element that outputs the light of 450 nm and the element that outputs the light of 405 nm in combination can be adopted.

### Advantageous Effects of Embodiment

Characteristics of the present embodiment are summarized as follows.
(1) The light emitting device 100 (lighting device) includes the phosphor application printed wiring board 30 in which the phosphor layer 36 is provided on the substrate surface (surface 31), the first light emitting unit 20A provided in the phosphor application printed wiring board 30 and outputting the light having a peak wavelength of the first wavelength, and
the second light emitting unit 20B provided in the phosphor application printed wiring board 30 and outputting the light having a peak wavelength of the second wavelength different from the first wavelength,
wherein the phosphor layer 36 is provided separately from the first light emitting unit 20A and the second light emitting unit 20B at least around the first light emitting unit 20A and the second light emitting unit 20B, and includes the phosphor in which the light emission peak wavelength is in the visible light region when the light having the first wavelength and the light having the second wavelength are emitted as the excitation light.

In this manner, the light emitting device 100 (the lighting device) that efficiently emits the light and emits the light with a desired light emission color can be realized. In other words, glares can be reduced as the light emitting device 100, and the output color tone can be adjusted.
(2) The peak wavelength of the first wavelength may be in the wavelength region of the visible light.

For example, when the first light emitting unit 20A is the LED that outputs the white light, the glares may be strongly recognized, but the glares can be reduced. In addition, even when the color tone is different from that of natural light in only the first light emitting unit 20A, a more natural color tone can be realized.
(3) The peak wavelength of the second wavelength may be in a range of 415 nm or longer and 460 nm or shorter.
(4) The peak wavelength of the second wavelength may be in a range of 315 nm or longer and 415 nm or shorter.
(5) The sealing material that seals the light emitting element of the second light emitting unit 20B may be colorless and transparent.
(6) The first light emitting unit 20A and the second light emitting unit 20B may be connected in series.

Since the first light emitting unit 20A and the second light emitting unit 20B are connected in series, the current values flowing through the first light emitting unit 20A and the second light emitting unit 20B can be the same as each other, and the output (intensity) of each light is easily adjusted. In particular, when the LED elements having different forward voltage VF characteristics are used as the first light emitting unit 20A and the second light emitting unit 20B, the currents can be stably supplied to the first light emitting unit 20A and the second light emitting unit 20B as designed.
(7) The serial body in which the plurality of first light emitting units 20A and at least one second light emitting unit 20B are connected in series may be provided.

Since the plurality of first light emitting units 20A are connected in series, it is possible to suppress variations in the intensity of the light of the first light emitting unit 20A.
(8) The serial body may include the plurality of second light emitting units 20B connected in series.

Since the plurality of second light emitting units 20B are connected in series, variations in the intensity of the light of the second light emitting unit 20B can be suppressed.
(9) The serial body may include the plurality of second light emitting units connected in parallel.

Since the plurality of second light emitting units 20B are connected in parallel, a degree of freedom in adopting a circuit configuration is improved. Even when the intensity of the light of the second light emitting unit 20B varies, the variations can be absorbed since the phosphor layer 36 is provided.
(10) The plurality of serial bodies may be connected in parallel.
(11) The light emitting element 22 of the first light emitting unit 20A and the light emitting element 22 of the second light emitting unit 20B are the light emitting diode elements (LEDs).
(12) The current adjusting resistor 25 that adjusts the current flowing through the first light emitting unit 20A may be provided.

In the circuit in which the plurality of serial bodies are connected in parallel, the current value of each serial body can be constant, and variations in the output light can be reduced.
(13) There is provided the circuit pattern layer 34 (circuit pattern) on which the first light emitting unit 20A and the second light emitting unit 20B are mounted.

The circuit pattern layer 34 includes the positive potential portion provided on the substrate center side and the ground potential portion provided on the substrate outer peripheral side, as the path supplying electric power to the first light emitting unit 20A and the second light emitting unit 20B. According to this configuration, the circuit configuration can be simplified.
(14) There is provided the photocatalyst unit that exhibits the photocatalyst function by using the light having the second wavelength output from the second light emitting unit 20B.

In this manner, an environment where the light emitting device 100 is disposed can be cleaned. In addition, the light having a short wavelength such as the blue light or the near-ultraviolet light (ultraviolet ray) is used as the photocatalyst excitation light. Accordingly, even when the output light is shifted to the blue side, the shift to the blue side can be suppressed by the phosphor layer 36.

Hitherto, each of the above-described embodiments of the present invention has been described as an example. However, the present invention is not limited to each of the above-described embodiments. The light emission color of the light emitting unit 20 may be different for each serial body or each parallel body. When the drive circuit 140 drives the light emitting unit 20 to emit the light, various types of dimming and toning can be performed by adjusting the output for each serial body or each parallel body or by adjusting a light emission timing.

This application claims priority based on Japanese Application No. 2021-106374, filed Jun. 28, 2021, the entire disclosure of which is hereby incorporated.

### REFERENCE SIGNS LIST

2A first region
2B second region
2C third region
10 light emitting substrate
20 light emitting unit
20A, 20A1 to 20A7 first light emitting unit
20B, 20B1, 20B2 second light emitting unit
22 light emitting element
23 sealing resin
30 phosphor application printed wiring board
31 surface
32 insulating substrate
33 back surface
34 circuit pattern layer
38 core metal
34A, 34B electrode pair
34C wiring portion
36 phosphor layer
37 central opening
70 connector
70A connector (+)
70B connector (GND)
100 light emitting device
110 cover member
130 body portion
131 heat radiating opening
140 drive circuit

1. A lighting device comprising:
a phosphor application printed wiring board in which a phosphor layer is provided on a substrate surface;
at least one first light emitting unit provided in the phosphor application printed wiring board and outputting light having a peak wavelength of a first wavelength; and
at least one second light emitting unit provided in the phosphor application printed wiring board and outputting light having a peak wavelength of a second wavelength different from the first wavelength,
wherein the phosphor layer is provided separately from the first light emitting unit and the second light emitting unit at least around the first light emitting unit and the second light emitting unit, and includes a phosphor in which
a light emission peak wavelength is in a visible light region when the light having the first wavelength and the light having the second wavelength are emitted as excitation light.

2. The lighting device according to claim 1,
wherein the peak wavelength of the first wavelength is a wavelength region of visible light.

3. The lighting device according to claim 1,
wherein the peak wavelength of the second wavelength is in a range of 415 nm or longer and 460 nm or shorter.

4. The lighting device according to claim 1,
wherein the peak wavelength of the second wavelength is in a range of 315 nm or longer and 415 nm or shorter.

5. The lighting device according to claim 1,
wherein a sealing material that seals a light emitting element of the second light emitting unit is colorless and transparent.

6. The lighting device according to claim 1, further comprising:
a serial body in which the at least one first light emitting unit and the at least one second light emitting unit are connected in series.

7. The lighting device according to claim 6,
wherein the serial body includes a plurality of the first light emitting units connected in series.

8. The lighting device according to claim 6,
wherein the serial body includes a plurality of the second light emitting units connected in series.

9. The lighting device according to claim 6,
wherein the serial body includes a plurality of the second light emitting units connected in parallel.

10. The lighting device according to claim 6,
wherein a plurality of the serial bodies are connected in parallel.

11. The lighting device according to claim 1,
wherein a light emitting element of the first light emitting unit and a light emitting element of the second light emitting unit are light emitting diode elements.

12. The lighting device according to claim 1, further comprising:
an adjusting resistor that adjusts a current flowing through the first light emitting unit.

13. The lighting device according to claim 1, further comprising:
a circuit pattern on which the first light emitting unit and the second light emitting unit are mounted,
wherein the circuit pattern includes a positive potential portion provided on a substrate center side and a ground potential portion provided on a substrate outer peripheral side, as a path for supplying electric power to the first light emitting unit and the second light emitting unit.

14. The lighting device according to claim 1, further comprising:
a photocatalyst unit that exhibits a photocatalyst function by using the light having the second wavelength output from the second light emitting unit.
